(19) United States
(12) Patent Application Publication
(10) Pub. No.: US 2026/0066913 A1
(43) Pub. Date: Mar. 5, 2026

(54) SUCCESSIVE-APPROXIMATION REGISTER ADC AND CALIBRATION METHOD THEREOF FOR CALIBRATING SETTLING TIME

(71) Applicant: Nuvoton Technology Corporation, Hsinchu Science Park (TW)

(72) Inventors: YI-CHING LU, Hsinchu Science Park (TW); Chung-Ming HSIEH, Zhubei City (TW)

(21) Appl. No.: 19/293,237

(22) Filed: Aug. 7, 2025

(30) Foreign Application Priority Data
Sep. 4, 2024 (TW) 113133444

(51) Int. Cl. H03M 1/10

(52) U.S. Cl. CPC H03M 1/1009

(57) ABSTRACT

A successive-approximation register analog-to-digital converter includes a first digital-to-analog converter, a comparator, a successive-approximation controller, and a calibration controller. The first digital-to-analog converter generates a difference voltage based on an input voltage and a digital code. The digital code corresponds to a sum of the input voltage and the difference voltage. When the difference voltage exceeds a threshold, the comparator sets a comparison signal to an enabled state. The successive-approximation controller adjusts the digital code based on the comparison signal, so that the digital code corresponds to the input voltage. The calibration controller executes a calibration process to determine a delay time from the digital code changing to the comparison signal switching from a disabled state to the enabled state.

### CROSS REFERENCE TO RELATED APPLICATIONS

This application claims priority of Taiwan Patent Application No. 113133444, filed on Sep. 4, 2024, the entirety of which is incorporated by reference herein.

### BACKGROUND OF THE INVENTION

### Field of the Invention

The disclosure is generally related to a successive-approximation register ADC and a calibration method thereof, and more particularly it is related to a successive-approximation register ADC and a calibration method thereof for calibrating the settling time.

### Description of the Related Art

Since the settling time required after each bit flip of a digital-to-analog converter in an asynchronously-controlled successive-approximation register ADC (SAR ADC) is different, the delay time between the change of the digital code input to the digital-to-analog converter and the comparison by the comparator is inconsistent. This causes the comparator to produce comparison errors, which in turn lead to conversion errors in the successive-approximation register analog-to-digital converter.

Therefore, it is necessary to correct the settling time required after each bit flip of a digital-to-analog converter in a successive-approximation register analog-to-digital converter. This way, the comparator performs comparisons with an appropriate delay time after each bit of the digital-to-analog converter flips, thereby allowing the successive-approximation register analog-to-digital converter to perform conversions quickly and correctly.

### BRIEF SUMMARY OF THE INVENTION

A successive-approximation register analog-to-digital converter and a calibration method thereof for calibrating the settling time has been proposed herein. By calibrating the settling time required after flipping each bit or any two consecutive bits of the digital code, the comparator can make comparisons for the correct difference voltage, so as to increase accuracy. In addition, since the settling time required after the digital code is flipped is determined, the time required for the successive-approximation register analog-to-digital converter to convert the input voltage to the digital code can also be accurately controlled, thereby increasing the conversion efficiency of the successive-approximation register analog-to-digital converter.

In an embodiment, a successive-approximation register analog-to-digital converter comprises a first digital-to-analog converter, a comparator, a successive-approximation controller, and a calibration controller. The first digital-to-analog converter is configured to generate a difference voltage based on an input voltage and a digital code. The digital code corresponds to a sum of the input voltage and the difference voltage. When the difference voltage exceeds a threshold, the comparator sets a comparison signal to an enabled state. The successive-approximation controller is configured to adjust the digital code based on the comparison signal so that the digital code corresponds to the input voltage. The calibration controller is configured to execute a calibration process to determine a delay time from when the digital code is changed to when the comparison signal is switched from a disabled state to the enabled state.

According to an embodiment of the invention, the successive-approximation register analog-to-digital converter further comprises a second digital-to-analog converter. The second digital-to-analog converter is configured to cancel the offset of the comparator. The first digital-to-analog converter comprises a plurality of capacitors. The second digital-to-analog converter is further configured to compensate for a mismatch among the plurality of capacitors of the first digital-to-analog converter.

According to an embodiment of the invention, a maximum of the delay time occurs when a most significant bit and a secondary most significant bit of the digital code are both flipped. The secondary most significant bit is adjacent to the most significant bit.

According to an embodiment of the invention, the calibration process comprises the following steps. A sampling voltage is sampled by the first digital-to-analog converter. When the first digital-to-analog converter samples the sampling voltage, the digital code is a sampling code corresponding to the sampling voltage. An initial code is input to the first digital-to-analog converter after the first digital-to-analog converter samples the sampling voltage. The initial code is changed to a target code. Whether the difference voltage exceeds the threshold is determined by the comparator. When the difference voltage exceeds the threshold, the comparison signal is switched from the disabled state to the enabled state. The delay time required from when the initial code is changed to the target code to when the comparison signal is switched to the enabled state is recorded.

According to an embodiment of the invention, in the step of changing the initial code to the target code, the first digital-to-analog converter generates the difference voltage based on the target code and the sampling voltage. When the difference voltage does not exceed the threshold, the comparator sets the comparison signal to the disabled state. The threshold is determined by a resolution of the comparator.

According to an embodiment of the invention, a target voltage corresponding to the target code exceeds the sampling voltage by a predetermined voltage. The predetermined voltage is equal to a voltage of a least significant bit of the digital code.

According to an embodiment of the invention, a voltage corresponding to the initial code is less than the sampling voltage. The target voltage exceeds the voltage corresponding to the initial code.

According to an embodiment of the invention, the initial code becomes the target code after any two consecutive bits of the initial code are both flipped. The delay time required for flipping any two consecutive bits of the initial code is different.

According to an embodiment of the invention, the initial code becomes the target code after any bit of the initial code is flipped.

According to an embodiment of the invention, when the successive-approximation controller adjusts the digital code again, the successive-approximation controller delays a corresponding delay time to sample the comparison signal once again.

In another embodiment, a calibration method for calibrating a successive-approximation register analog-to-digital converter is provided. The successive-approximation register analog-to-digital converter comprises a first digital-to-analog converter and a comparator. The first digital-to-analog converter is configured to generate a digital code corresponding to an input voltage. The calibration method comprises the following steps. A sampling voltage is sampled by the first digital-to-analog converter. After the first digital-to-analog converter samples the sampling voltage, an initial code is input to the first digital-to-analog converter. The initial code is changed to a target code to make the first digital-to-analog converter generate a difference voltage based on the target code and the sampling voltage. Whether the difference voltage exceeds a threshold is determined by the comparator. When the difference voltage exceeds the threshold, a comparison signal is switched from a disabled state to an enabled state. A delay time from when the initial code is changed to the target code to when the comparison signal is switched to the enabled state is recorded.

According to an embodiment of the invention, after the successive-approximation register analog-to-digital converter changes the digital code input to the first digital-to-analog converter and then delays the corresponding delay time, the successive-approximation register analog-to-digital converter adjusts the digital code based on the comparison signal once again, so that the digital code successively approaches the input voltage.

According to an embodiment of the invention, the successive-approximation register analog-to-digital converter further comprises a second digital-to-analog converter. The second digital-to-analog converter is configured to cancel an offset of the comparator. The first digital-to-analog converter comprises a plurality of capacitors. The second digital-to-analog converter is further configured to compensate for a mismatch among the plurality of capacitors of the first digital-to-analog converter.

According to an embodiment of the invention, when the successive-approximation register analog-to-digital converter changes the digital code, any two consecutive bits of the digital code are flipped.

According to an embodiment of the invention, a maximum of the delay time occurs when a most significant bit and a secondary most significant bit of the digital code are both flipped. The secondary most significant bit is adjacent to the most significant bit.

According to an embodiment of the invention, when the successive-approximation register analog-to-digital converter changes the digital code, only one bit of the digital code is flipped.

According to an embodiment of the invention, the threshold is determined by a resolution of the comparator.

According to an embodiment of the invention, a target voltage corresponding to the target code exceeds the sampling voltage by a predetermined voltage. The predetermined voltage is equal to a voltage corresponding to a least significant bit of the digital code.

According to an embodiment of the invention, a voltage corresponding to the initial code is less than the sampling voltage. The target voltage exceeds the voltage corresponding to the initial code.

According to an embodiment of the invention, the calibration method further comprises the following steps. When the difference voltage does not exceed the threshold, the step of determining whether the difference voltage exceeds the threshold by the comparator is executed.

A detailed description is given in the following embodiments with reference to the accompanying drawings.

### BRIEF DESCRIPTION OF DRAWINGS

The invention can be more fully understood by reading the subsequent detailed description and examples with references made to the accompanying drawings, wherein:

FIG. 1 is a block diagram showing a successive-approximation register analog-to-digital converter in accordance with an embodiment of the present invention;

FIG. 2 is a schematic diagram showing a first digital-to-analog converter in accordance with an embodiment of the present invention;

FIG. 3 is a flow chart showing a calibration method in accordance with an embodiment of the present invention;

FIG. 4 is a schematic diagram showing a calibration method in accordance with an embodiment of the present invention;

FIG. 5 is a block diagram showing a successive-approximation register analog-to-digital converter in accordance with another embodiment of the present invention;

FIG. 6 is a schematic diagram showing a first digital-to-analog converter and a second digital-to-analog converter in accordance with an embodiment of the present invention; and

FIG. 7 is a schematic diagram showing an equivalent circuit in accordance with an embodiment of the present invention.

### DETAILED DESCRIPTION OF THE INVENTION

The following description is made for the purpose of illustrating the general principles of the disclosure and should not be taken in a limiting sense. The scope of the disclosure is determined by reference to the appended claims.

In the following detailed description, for purposes of explanation, numerous specific details and embodiments are set forth in order to provide a thorough understanding of the present disclosure. The use of like and/or corresponding numerals in the drawings of different embodiments does not suggest any correlation between different embodiments.

In addition, in some embodiments of the present disclosure, terms concerning attachments, coupling and the like, such as “connected” and “interconnected,” refer to a relationship wherein structures are secured or attached to one another either directly or indirectly (for example, electrically connection) via intervening structures, as well as both movable or rigid attachments or relationships, unless expressly described otherwise.

In addition, in this specification, relative spatial expressions are used. For example, “lower”, “bottom”, “higher” or “top” are used to describe the position of one element relative to another. It should be appreciated that if a device is flipped upside down, an element that is “lower” will become an element that is “higher”.

It should be understood that, although the terms first, second, third etc. may be used herein to describe various elements, components, regions, layers, portions and/or sections, these elements, components, regions, layers, portions and/or sections should not be limited by these terms. These terms are only used to distinguish one element, component, region, layer, portion or section from another element, component, region, layer or section. Thus, a first element, component, region, layer, portion or section in the specification could be termed a second element, component, region, layer, portion or section in the claims without departing from the teachings of the present disclosure.

It should be understood that this description of the exemplary embodiments is intended to be read in connection with the accompanying drawings, which are to be considered part of the entire written description. The drawings are not drawn to scale. In addition, structures and devices are shown schematically in order to simplify the drawing.

The terms “approximately”, “about” and “substantially” typically mean a value is within a range of +/−20% of the stated value, more typically a range of +/−10%, +/−5%, +/−3%, +/−2%, +/−1% or +/−0.5% of the stated value. The stated value of the present disclosure is an approximate value. Even there is no specific description, the stated value still includes the meaning of “approximately”, “about” or “substantially”.

Unless defined otherwise, all technical and scientific terms used herein have the same meaning as commonly understood by one of ordinary skill in the art to which this disclosure belongs. It should be appreciated that, in each case, the term, which is defined in a commonly used dictionary, should be interpreted as having a meaning that conforms to the relative skills of the present disclosure and the background or the context of the present disclosure, and should not be interpreted in an idealized or overly formal manner unless so defined.

In addition, in some embodiments of the present disclosure, terms concerning attachments, coupling and the like, such as “connected” and “interconnected,” refer to a relationship wherein structures are secured or attached to one another either directly or indirectly (for example, electrically connection) via intervening structures, as well as both movable or rigid attachments or relationships, unless expressly described otherwise.

In the drawings, similar elements and/or features may have the same reference number. Various components of the same type can be distinguished by adding letters or numbers after the component symbol to distinguish similar components and/or similar features.

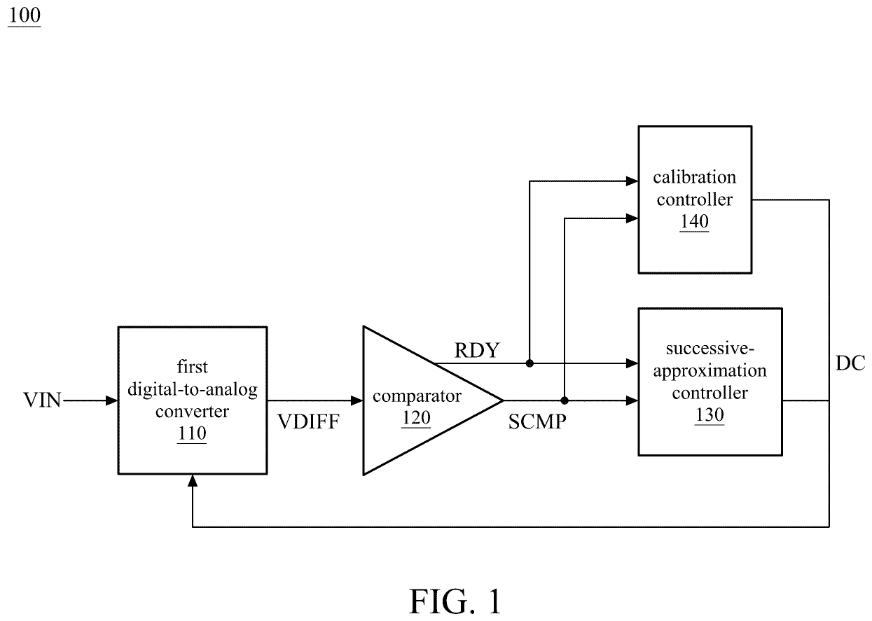

FIG. 1 is a block diagram showing a successive-approximation register analog-to-digital converter in accordance with an embodiment of the present invention. As shown in FIG. 1, the successive-approximation register analog-to-digital converter 100 is configured to convert the input voltage VIN into a digital code DC, and includes a first digital-to-analog converter 110, a comparator 120, and a successive-approximation controller 130.

The first digital-to-analog converter 110 samples the input voltage VIN, and generates a difference voltage VDIFF based on the input voltage VIN and the digital code DC. The comparator 120 is configured to compare the difference voltage VDIFF with a threshold value, to determine whether the difference voltage VDIFF exceeds the threshold value to generate a comparison signal SCMP. In addition, when the comparison by the comparator 120 is completed, the completion signal RDY is changed from the disabled state to the enabled state. According to some embodiments of the present invention, when the digital code DC is updated, the comparator 120 almost immediately determines whether the difference voltage VDIFF exceeds the threshold value to generate the comparison signal SCMP, and simultaneously sets the completion signal RDY to the enabled state. However, since the difference voltage VDIFF still needs a settling time to reach the correct value after the digital code DC is updated, the comparison signal SCMP immediately generated by the comparator 120 is not the correct result.

According to an embodiment of the present invention, when the difference voltage VDIFF exceeds the threshold value, the comparison signal SCMP is in an enabled state; when the difference voltage VDIFF does not exceed the threshold value, the comparison signal SCMP is in a disabled state. According to some embodiments of the present invention, the threshold value is determined by the resolution of the comparator 120. According to some embodiments of the present invention, the threshold value is not greater than half of the voltage corresponding to the least significant bit (LSB) of the digital code DC.

The successive-approximation controller 130 samples the comparison signal SCMP based on the completion signal RDY being at the enabled state, and adjusts the digital code DC based on the state of the comparison signal SCMP, so that the digital code DC corresponds to the input voltage VIN. According to some embodiments of the present invention, the first digital-to-analog converter 110 generates a conversion voltage based on the digital code DC, where the conversion voltage is equal to the sum of the input voltage VIN and the difference voltage VDIFF.

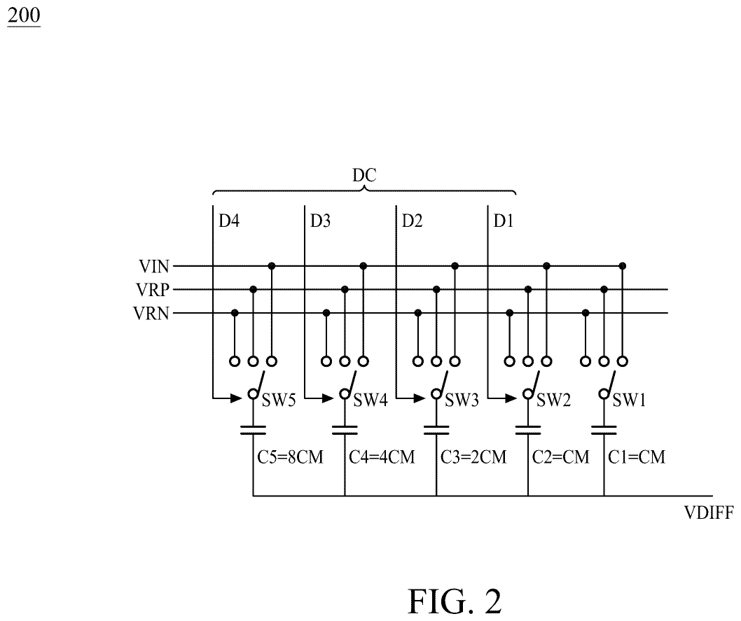

FIG. 2 is a schematic diagram showing a first digital-to-analog converter in accordance with an embodiment of the present invention. In the embodiment of FIG. 2, the first digital-to-analog converter 200 is illustrated as a 4-bit digital-to-analog conversion circuit, but not intended to be limited thereto. According to some embodiments of the present invention, the first digital-to-analog converter 200 may have a differential output, so that the comparator 120 in FIG. 1 is configured to determine whether the difference voltage VDIFF is a positive value or a negative value. In order to simplify the explanation, the first digital-to-analog converter 200 is illustrated as a single-ended converter herein, and the comparator 120 in FIG. 1 compares the difference voltage VDIFF generated by the first digital-to-analog converter 200 with the threshold value, but not intended to be limited thereto.

As shown in FIG. 2, the first digital-to-analog converter 200 includes a first capacitor C1, a second capacitor C2, a third capacitor C3, a fourth capacitor C4, and a fifth capacitor C5. The capacitance value of the first capacitor C1 and that of the second capacitor C2 are both the main capacitance value CM; the capacitance value of the third capacitor C3 is twice the capacitance value of the second capacitor C2; the capacitance value of the fourth capacitor C4 is the third capacitance value CM. The capacitance value of the capacitor C3 is twice that of the fifth capacitor C5; the capacitance value of the fifth capacitor C5 is twice that of the fourth capacitor C4.

As shown in FIG. 2, the first digital-to-analog converter 200 further includes a first switch SW1, a second switch SW2, a third switch SW3, a fourth switch SW4, and a fifth switch SW5. The first switch SW1, the second switch SW2, the third switch SW3, the fourth switch SW4, and the fifth switch SW5 are configured to electrically connect the first capacitor C1, the second capacitor C2, the third capacitor C3, the fourth capacitor C4, and the fifth capacitor C5 to one of the input voltage VIN, the positive reference voltage VRP, and the negative reference voltage VRN.

The digital code DC in FIG. 1 includes a first bit code D1, a second bit code D2, a third bit code D3, and a fourth bit code D4, which are configured to respectively control the second switch SW2, the third switch SW3, the fourth switch SW4 and the fifth switch SW5 in FIG. 2 to electrically connect to one of the input voltage VIN, the positive reference voltage VRP, and the negative reference voltage VRN.

According to some embodiments of the present invention, when the first digital-to-analog converter 200 samples the input voltage VIN, the input voltage VIN is stored in the first capacitor C1, the second capacitor C2, the third capacitor C3, and the fourth capacitor C4, and the fifth capacitor C5. The successive-approximation controller 130 in FIG. 1 adjusts the digital code DC to electrically connect the second capacitor C2, the third capacitor C3, the fourth capacitor C4, and the fifth capacitor C5 to one of the positive reference voltage VRP and the negative reference voltage VRN, so that the first digital-to-analog converter 200 generates a difference voltage VDIFF.

As shown in FIG. 2, the second capacitor C2, the third capacitor C3, the fourth capacitor C4, and the fifth capacitor C5 have different capacitance values, and charging and discharging time required for different capacitance values are different. As shown in FIG. 1, the settling time required by the successive-approximation controller 130 after changing the digital code DC is also different. Therefore, it is necessary to separately calibrate the settling times of the second capacitor C2, the third capacitor C3, the fourth capacitor C4, and the fifth capacitor C5 so as to obtain the best individual settling time.

Returning to FIG. 1, the successive-approximation register analog-to-digital converter 100 further includes a calibration controller 140. The calibration controller 140 executes the calibration method to perform a calibration process to calibrate the settling times required for the second capacitor C2, the third capacitor C3, the fourth capacitor C4, and the fifth capacitor C5 respectively, and store in the successive-approximation controller 130 (not shown in FIG. 1). When any one of the first bit D1, the second bit D2, the third bit D3, and the fourth bit D4 of the digital code DC is flipped, the successive-approximation controller 130 samples the comparison signal SCMP after the completion signal RDY is changed from the disabled state to the enabled state and a corresponding settling time has been delayed, and then the digital code DC can be adjusted again.

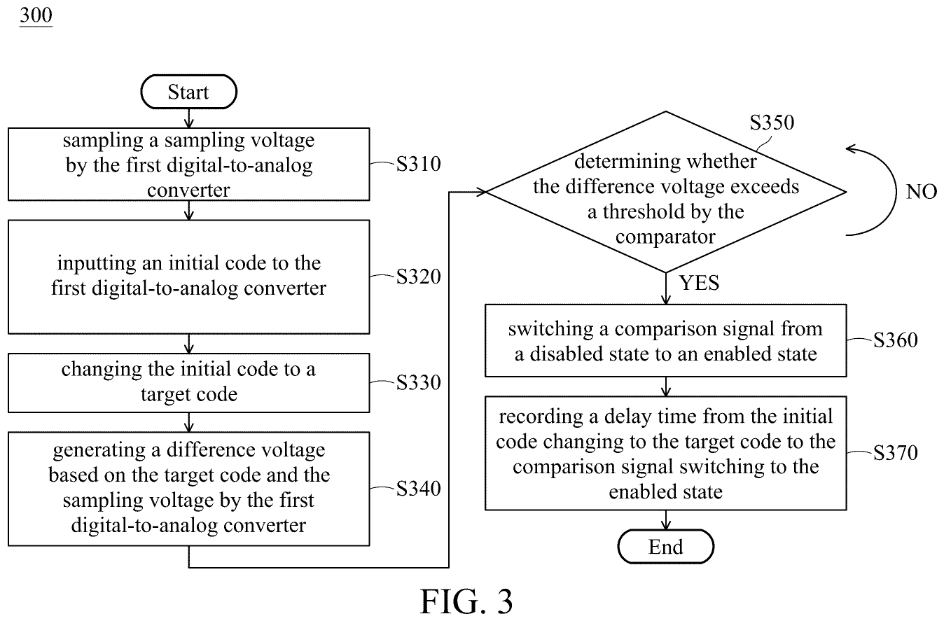

FIG. 3 is a flow chart showing a calibration method in accordance with an embodiment of the present invention. The following description of the calibration method 300 will be described in detail in conjunction with the successive-approximation register analog-to-digital converter 100 in FIG. 1.

As shown in FIG. 3, first in Step S310, the first digital-to-analog converter 110 is configured to sample a sampling voltage (as the input voltage VIN), where the sampling voltage corresponds to the sampling code DSMP. According to some embodiments of the present invention, when the first digital-to-analog converter 110 samples the sampling voltage, the digital code DC of the first digital-to-analog converter 110 is also switched to the sampling code DSMP.

After the first digital-to-analog converter 110 samples the sampling voltage, the calibration controller 140 inputs the initial code DINT (as the digital code DC) to the first digital-to-analog converter 110 (Step S320). Next, the calibration controller 140 changes the initial code DINT to the target code DTAR (Step S330), and uses the first digital-to-analog converter 110 to generate the difference voltage VDIFF based on the sampling voltage corresponding to the sampling code DSMP and the target code DTAR (Step S340).

Next, the comparator 120 is configured to determine whether the difference voltage VDIFF exceeds a threshold value (Step S350), where the threshold value is determined by the resolution of the comparator 120. According to some embodiments of the present invention, the threshold value is half of the voltage corresponding to the least significant bit of the digital code DC. When the comparator 120 determines that the difference voltage VDIFF exceeds the threshold value, the comparator 120 changes the comparison signal SCMP from the disabled state to the enabled state (Step S360). Finally, the delay time required from the initial code DINT changing to the target code DTAR to the comparison signal SCMP changing to the enabled state is recorded (Step S370).

According to some embodiments of the present invention, the voltage corresponding to the initial code DINT is less than the sampling voltage, and the voltage corresponding to the target code DTAR is higher than the sampling voltage corresponding to the sampling code DSMP by the voltage corresponding to the least significant bit of the digital code DC, and the initial code DINT only flips one bit to become the target code DTAR. The relationship of the sampling code DSMP, initial code DINT and target code DTAR is shown in Table 1.

TABLE 1

| DSMP | DINT | DTAR |
|---|---|---|
| 0111 | 0000 | 1000 |
| 1011 | 1000 | 1100 |
| 1101 | 1100 | 1110 |
| 1110 | 1110 | 1111 |

According to some embodiments of the present invention, since the operation mode of the successive-approximation register analog-to-digital converter 100 searching the digital code DC corresponding to the input voltage VIN is to only flip one bit of the digital code DC in each cycle to generate the corresponding voltage compared with the input voltage VIN, the relationship of the initial code DINT and the target code DTAR shown in Table 1 reproduces the operation mode of the successive-approximation register analog-to-digital converter 100. In other words, the delay time obtained in Step S370 is the settling time required after each bit of the digital code DC is flipped.

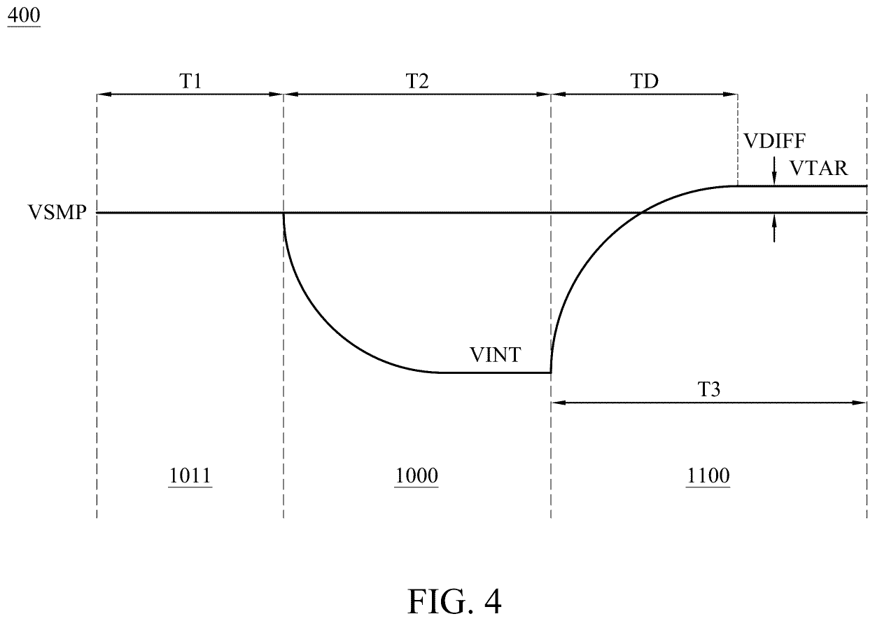

FIG. 4 is a schematic diagram showing a calibration method in accordance with an embodiment of the present invention. During the first period T1, the calibration controller 140 executes Step S310, the first digital-to-analog converter 110 samples the sampling voltage VSMP, and the digital code DC inside the first digital-to-analog converter 110 is 1011. During the second period T2, the calibration controller 140 executes Step S320, the digital code DC is changed to the initial code DINT (i.e., 1000), and the initial voltage VINT corresponding to the initial code DINT is smaller than the sampling voltage VSMP.

In the third period T3, the digital code DC changes to the target code DTAR (i.e., Step S330), and the initial voltage VINT rises to the target voltage VTAR corresponding to the target code DTAR after the delay time TD. After the delay time TD, the comparator 120 determines that the difference voltage VDIFF exceeds the threshold value to set the comparison signal SCMP to the enabled state. In other words, the delay time TD in FIG. 4 is the settling time of the third bit code D3 of the digital code DC.

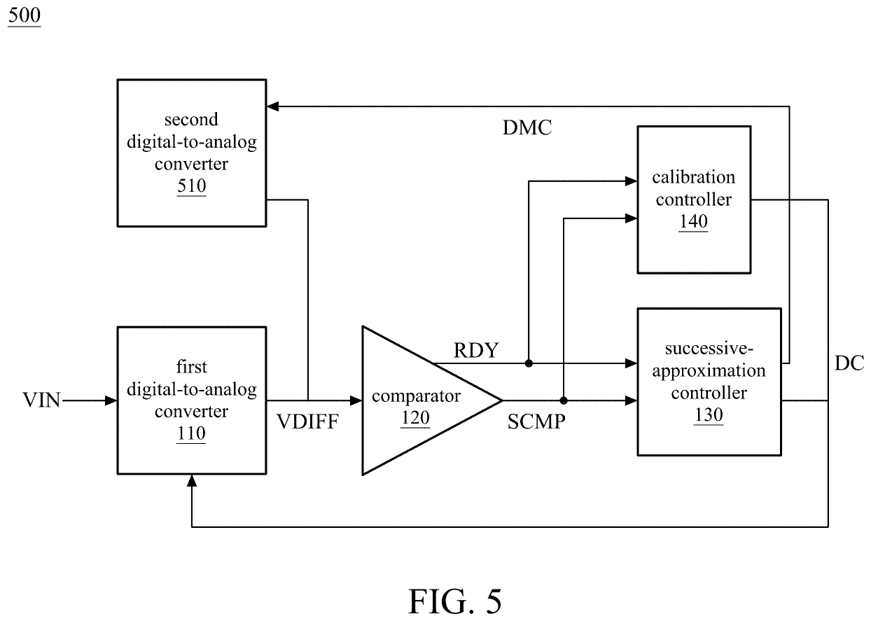

FIG. 5 is a block diagram showing a successive-approximation register analog-to-digital converter in accordance with another embodiment of the present invention. As shown in FIG. 5, the successive-approximation register analog-to-digital converter 500 further includes a second digital-to-analog converter 510 compared to the successive-approximation register analog-to-digital converter 100 in FIG. 1, and the second digital-to-analog converter 510 receives a digital compensation code DMC from the successive-approximation controller 130. According to some embodiments of the present invention, the second digital-to-analog converter 510 is configured to eliminate the offset of the comparator 120. According to other embodiments of the present invention, the second digital-to-analog converter 510 is configured to compensate for the non-ideal effects of the first digital-to-analog converter 110. According to some embodiments of the present invention, the above-mentioned non-ideal effects include the mismatch among the capacitors of the first digital-to-analog converter 110.

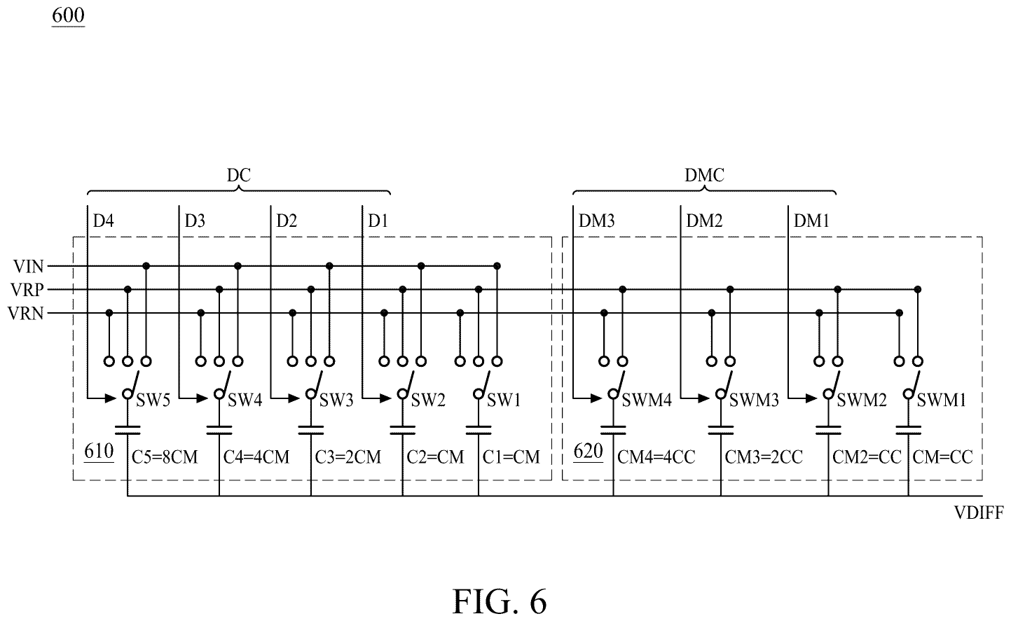

FIG. 6 is a schematic diagram showing a first digital-to-analog converter and a second digital-to-analog converter in accordance with an embodiment of the present invention. According to some embodiments of the present invention, the first digital-to-analog converter 610 and the second digital-to-analog converter 620 in FIG. 6 correspond to the first digital-to-analog converter 110 and the second digital-to-analog converter 510 in FIG. 5 respectively. As shown in FIG. 6, the first digital-to-analog converter 610 is the identical to the first digital-to-analog converter 200 in FIG. 2, which will not be repeated herein.

As shown in FIG. 6, the second digital-to-analog converter 620 includes a first compensation capacitor CM1, a second compensation capacitor CM2, a third compensation capacitor CM3, and a fourth compensation capacitor CM4. The capacitance values of the first compensation capacitor CM1 and the second compensation capacitor CM2 are both the compensation capacitance value CC; the capacitance value of the third compensation capacitor CM3 is twice of the first compensation capacitor CM1; the capacitance value of the fourth compensation capacitor CM4 is twice of the third compensation capacitor CM3. In addition, one terminal of the first compensation capacitor CM1, the second compensation capacitor CM2, the third compensation capacitor CM3, and the fourth compensation capacitor CM4 is electrically connected to the difference voltage VDIFF.

As shown in FIG. 6, the second digital-to-analog converter 620 further includes a first compensation switch SWM1, a second compensation switch SWM2, a third compensation switch SWM3, and a fourth compensation switch SWM4. The first compensation switch SWM1, the second compensation switch SWM2, the third compensation switch SWM3, and the fourth compensation switch SWM4 are configured to electrically connect the first compensation capacitor CM1, the second compensation capacitor CM2, the third compensation capacitor CM3, and the fourth compensation capacitor CM4 to the positive reference voltage VRP or the negative reference voltage VRN.

The compensation digital code DMC in FIG. 5 includes a first compensation bit code DM1, a second compensation bit code DM2, and a third compensation bit code DM3, configured to respectively control the second compensation switch SWM2, the third compensation switch SWM3, and the fourth compensation switch SWM4 in FIG. 6 to be electrically connected to the positive reference voltage VRP or the negative reference voltage VRN.

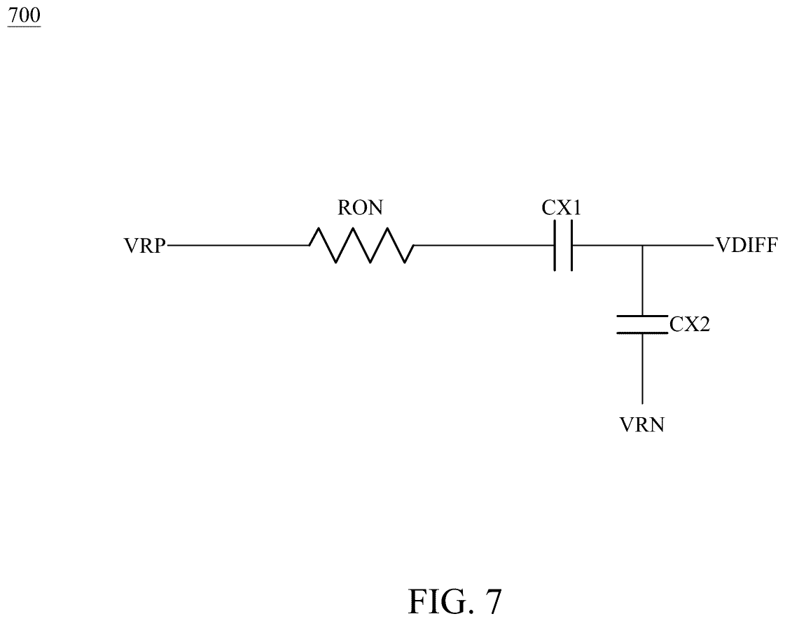

FIG. 7 is a schematic diagram showing an equivalent circuit in accordance with an embodiment of the present invention. According to some embodiments of the present invention, the settling time of the difference voltage VDIFF in FIG. 2 and the difference voltage VDIFF in FIG. 6 can be represented by an equivalent circuit 700. As shown in FIG. 7, the on-resistance RON represents the on-resistance of the switch, the first equivalent capacitor CX1 represents the capacitance electrically connected between the positive reference voltage VRP and the difference voltage VDIFF, and the second equivalent capacitor CX2 represents the capacitance electrically connected between the difference voltage VDIFF and the negative reference voltage VRN.

In order to simplify the explanation in the following paragraphs, it is illustrated that the negative reference voltage VRN is 0V and the main capacitance value CM and the compensation capacitance value CC are equal to the capacitance value C, but it is not intended to be limited thereto. The relationship between the difference voltage VDIFF, the positive reference voltage VRP and the negative reference voltage VRN (i.e., 0V) is as shown in Eq. 1 and Eq. 2.

$$\begin{matrix}VDIFF = VRP \times \frac{\frac{1}{sCX 2}}{( RON + \frac{1}{sCX 1} ) + \frac{1}{sCX 2}} \\ = VRP \times \frac{1}{1 + sRON ( \frac{CX 1 \cdot CX 2}{CX 1 + CX 2} )}\end{matrix} \qquad ( Eq . 1 )$$

$$VDIFF ( t ) = \frac{CX 1}{CX 1 + CX 2} \cdot VRP \cdot ( 1 - {e}^{- 1 / RON \cdot {C}^{′}} ) {C}^{′} = \frac{CX 1 \cdot CX 2}{CX 1 + CX 2} \qquad ( Eq . 2 )$$

As shown in Eq. 1 and Eq. 2, the settling time of the difference voltage VDIFF (that is, the delay time TD in FIG. 4) is determined by the on-resistance RON and C′ of Eq. 2 (that is,

$$\frac{CX 1 \cdot CX 2}{CX 1 + CX 2} ) .$$

Since the on-resistance RON of the switch is very small, the settling time of the difference voltage VDIFF can be regarded as being determined by C′ of Eq. 2.

When the first digital-to-analog converter 200 in FIG. 2 only flips the most significant bit (i.e., the fourth bit code D4 flips from a low logic level to a high logic level), C′ is as shown in Eq. 3.

$$\begin{matrix}{C}^{′} = \frac{CX 1 \cdot CX 2}{CX 1 + CX 2} \\ = \frac{8 C \cdot 8 C}{( 8 + 4 + 2 + 1 + 1 ) C} \\ = 4 C\end{matrix} \qquad ( Eq . 3 )$$

When the first digital-to-analog converter 200 in FIG. 2 only flips the secondary most significant bit (i.e., the third bit code D3 flips from a low logic level to a high logic level), C″ is as shown in Eq. 4.

$$\begin{matrix}{C}^{′} = \frac{CX 1 \cdot CX 2}{CX 1 + CX 2} \\ = \frac{4 C \cdot 12 C}{( 8 + 4 + 2 + 1 + 1 ) C} \\ = 3 C\end{matrix} \qquad ( Eq . 4 )$$

When the first digital-to-analog converter 200 in FIG. 2 simultaneously flips the most significant bit (i.e., the fourth bit code D4 flips from a low logic level to a high logic level) and the secondary most significant bit (i.e., the When the three-digit code D3 flips from a low logic level to a high logic level), C′ is as shown in Eq. 5.

$$\begin{matrix}{C}^{′} = \frac{CX 1 \cdot CX 2}{CX 1 + CX 2} \\ = \frac{4 C \cdot 12 C}{( 8 + 4 + 2 + 1 + 1 ) C} \\ = 3 C\end{matrix} \qquad ( Eq . 5 )$$

As shown in Eq. 3, Eq. 4 and Eq. 5, it can be seen that the settling time when the first digital-to-analog converter 200 only flips the most significant bit (i.e., the fourth bit code D4 flips from a low logic level to a high logic level) is the longest.

In FIG. 6, a second digital-to-analog converter 620 is added to eliminate the offset of the comparator 120 and compensate for the mismatch between the capacitors of the first digital-to-analog converter 610. When the first digital-to-analog converter 610 in FIG. 6 only flips the most significant bit (i.e., the fourth bit code D4), C′ is as shown in Eq. 6.

$$\begin{matrix}{C}^{′} = \frac{CX 1 \cdot CX 2}{CX 1 + CX 2} \\ = \frac{8 C \cdot [ ( 4 + 2 + 1 + 1 ) C + ( 4 + 2 + 1 + 1 ) C ]}{( 8 + 4 + 2 + 1 + 1 ) C + ( 4 + 2 + 1 + 1 ) C} \\ = 5.3 C\end{matrix} \qquad ( Eq . 6 )$$

When the first digital-to-analog converter 610 in FIG. 6 only flips the secondary most significant bit (i.e., the third bit code D3), C′ is as shown in Eq. 7.

$$\begin{matrix}{C}^{′} = \frac{CX 1 \cdot CX 2}{CX 1 + CX 2} \\ = \frac{4 C \cdot [ ( 8 + 2 + 1 + 1 ) C + ( 4 + 2 + 1 + 1 ) C ]}{( 8 + 4 + 2 + 1 + 1 ) C + ( 4 + 2 + 1 + 1 ) C} \\ = 3.33 C\end{matrix} \qquad ( Eq . 7 )$$

When the first digital-to-analog converter 610 in FIG. 6 flips the most significant bit (i.e., the fourth bit code D4) and the secondary most significant bit (i.e., the third bit code D3) at the same time, C′ is as shown in Eq. 8.

$$\begin{matrix}{C}^{′} = \frac{CX 1 \cdot CX 2}{CX 1 + CX 2} \\ = \frac{( 8 C + 4 C ) \cdot [ ( 2 + 1 + 1 ) C + ( 4 + 2 + 1 + 1 ) C ]}{( 8 + 4 + 2 + 1 + 1 ) C + ( 4 + 2 + 1 + 1 ) C} \\ = 6 C\end{matrix} \qquad ( Eq . 8 )$$

As shown in Eq. 6, Eq. 7 and Eq. 8, it can be seen that after adding the second digital-to-analog converter 620, the settling time at which the first digital-to-analog converter 610 flips the most significant bit (i.e., the fourth bit code D4) and the secondary most significant bit (i.e., the third bit code D3) at the same time is the longest. In addition, when the successive-approximation register analog-to-digital converter 500 searches for the digital code DC corresponding to the input voltage VIN, it is always needed to flip any two consecutive bits at the same time.

Therefore, if the successive-approximation register analog-to-digital converter 500 sets the delay time corresponding to only flipping the most significant bit to the maximum settling time, the delay time for the successive-approximation register analog-to-digital converter 500 flipping the most significant bit and the secondary most significant bit at the same time will be insufficient, which causes the comparator 120 to make an incorrect determination to generate an incorrect comparison signal SCMP.

In order to make the calibration process closer to the process of the successive-approximation register analog-to-digital converter 500 searching for the digital code DC corresponding to the input voltage VIN, the corrected sampling code DSMP, initial code DINT, and target code DTAR are shown in Table 2.

TABLE 2

| DSMP | DINT | DTAR |
|---|---|---|
| 0111 | 0000 | 1000 |
| 0111 | 0100 | 1000 |
| 0011 | 0010 | 0100 |
| 0001 | 0001 | 0010 |

As shown in Table 2, only the most significant bit or any two consecutive bits are flipped from the initial code DINT and the target code DTAR. The sampling code DSMP corresponding to the sampling voltage VSMP and the target code DTAR differ by the voltage corresponding to the least significant bit. According to other embodiments of the present invention, the calibration controller 140 in FIG. 5 can also perform the calibration method 300 in FIG. 3 for the sampling voltage VSMP (corresponding to the sampling code DSMP), the initial code DINT, and the target code DTAR in Table 1 and Table 2, leading to the settling time of flipping any bit or any two consecutive bits of the digital code DC more accurate.

A successive-approximation register analog-to-digital converter and a calibration method thereof for calibrating the settling time has been proposed herein. By calibrating the settling time required after flipping each bit or any two consecutive bits of the digital code, the comparator can make comparisons for the correct difference voltage, so as to increase accuracy. In addition, since the settling time required after the digital code is flipped is determined, the time required for the successive-approximation register analog-to-digital converter to convert the input voltage to the digital code can also be accurately controlled, thereby increasing the conversion efficiency of the successive-approximation register analog-to-digital converter.

Although some embodiments of the present disclosure and their advantages have been described in detail, it should be understood that various changes, substitutions and alterations can be made herein without departing from the spirit and scope of the disclosure as defined by the appended claims. For example, it will be readily understood by those skilled in the art that many of the features, functions, processes, and materials described herein may be varied while remaining within the scope of the present disclosure. Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A successive-approximation register analog-to-digital converter, comprising:
a first digital-to-analog converter, configured to generate a difference voltage based on an input voltage and a digital code, wherein the digital code corresponds to a sum of the input voltage and the difference voltage;
a comparator, wherein when the difference voltage exceeds a threshold, the comparator sets a comparison signal to an enabled state;
a successive-approximation controller, configured to adjust the digital code based on the comparison signal so that the digital code corresponds to the input voltage; and
a calibration controller, configured to execute a calibration process to determine a delay time from when the digital code is changed to when the comparison signal is switched from a disabled state to the enabled state.

2. The successive-approximation register analog-to-digital converter as claimed in claim 1, further comprising:
a second digital-to-analog converter, configured to cancel offset of the comparator;
wherein the first digital-to-analog converter comprises a plurality of capacitors;
wherein the second digital-to-analog converter is further configured to compensate for a mismatch among the plurality of capacitors of the first digital-to-analog converter.

3. The successive-approximation register analog-to-digital converter as claimed in claim 2, wherein a maximum of the delay time occurs when a most significant bit and a secondary most significant bit of the digital code are both flipped;
wherein the secondary most significant bit is adjacent to the most significant bit.

4. The successive-approximation register analog-to-digital converter as claimed in claim 2, wherein the calibration process comprises the following steps:
sampling a sampling voltage by the first digital-to-analog converter, wherein when the first digital-to-analog converter samples the sampling voltage, the digital code is a sampling code corresponding to the sampling voltage;
inputting an initial code to the first digital-to-analog converter after the first digital-to-analog converter samples the sampling voltage;
changing the initial code to a target code;
determining whether the difference voltage exceeds the threshold by the comparator;
when the difference voltage exceeds the threshold, switching the comparison signal from the disabled state to the enabled state; and
recording the delay time required from when the initial code is changed to the target code to when the comparison signal is switched to the enabled state.

5. The successive-approximation register analog-to-digital converter as claimed in claim 4, wherein in the step of changing the initial code to the target code, the first digital-to-analog converter generates the difference voltage based on the target code and the sampling voltage;
wherein when the difference voltage does not exceed the threshold, the comparator sets the comparison signal to the disabled state;
wherein the threshold is determined by a resolution of the comparator.

6. The successive-approximation register analog-to-digital converter as claimed in claim 5, wherein a target voltage corresponding to the target code exceeds the sampling voltage by a predetermined voltage;
wherein the predetermined voltage is equal to a voltage of a least significant bit of the digital code.

7. The successive-approximation register analog-to-digital converter as claimed in claim 6, wherein a voltage corresponding to the initial code is less than the sampling voltage;
wherein the target voltage exceeds the voltage corresponding to the initial code.

8. The successive-approximation register analog-to-digital converter as claimed in claim 4, wherein the initial code becomes the target code after any two consecutive bits of the initial code are both flipped;
wherein the delay time required for flipping any two consecutive bits of the initial code is different.

9. The successive-approximation register analog-to-digital converter as claimed in claim 4, wherein the initial code becomes the target code after any bit of the initial code is flipped.

10. The successive-approximation register analog-to-digital converter as claimed in claim 4, wherein when the successive-approximation controller adjusts the digital code again, the successive-approximation controller delays a corresponding delay time to sample the comparison signal once again.

11. A calibration method for calibrating a successive-approximation register analog-to-digital converter, wherein the successive-approximation register analog-to-digital converter comprises a first digital-to-analog converter and a comparator, wherein the first digital-to-analog converter is configured to generate a digital code corresponding to an input voltage, wherein the calibration method comprises:
sampling a sampling voltage by the first digital-to-analog converter;
after the first digital-to-analog converter samples the sampling voltage, inputting an initial code to the first digital-to-analog converter;
changing the initial code to a target code to make the first digital-to-analog converter generate a difference voltage based on the target code and the sampling voltage;
determining whether the difference voltage exceeds a threshold by the comparator;
when the difference voltage exceeds the threshold, switching a comparison signal from a disabled state to an enabled state; and
recording a delay time from when the initial code is changed to the target code to when the comparison signal is switched to the enabled state.

12. The calibration method as claimed in claim 11, wherein after the successive-approximation register analog-to-digital converter changes the digital code input to the first digital-to-analog converter and then delays the corresponding delay time, the successive-approximation register analog-to-digital converter adjusts the digital code based on the comparison signal once again, so that the digital code successively approaches the input voltage.

13. The calibration method as claimed in claim 12, wherein the successive-approximation register analog-to-digital converter further comprises a second digital-to-analog converter;
wherein the second digital-to-analog converter is configured to cancel an offset of the comparator;
wherein the first digital-to-analog converter comprises a plurality of capacitors;
wherein the second digital-to-analog converter is further configured to compensate for a mismatch among the plurality of capacitors of the first digital-to-analog converter.

14. The calibration method as claimed in claim 13, wherein when the successive-approximation register analog-to-digital converter changes the digital code, any two consecutive bits of the digital code are flipped.

15. The calibration method as claimed in claim 14, wherein a maximum of the delay time occurs when a most significant bit and a secondary most significant bit of the digital code are both flipped;
wherein the secondary most significant bit is adjacent to the most significant bit.

16. The calibration method as claimed in claim 13, wherein when the successive-approximation register analog-to-digital converter changes the digital code, only one bit of the digital code is flipped.

17. The calibration method as claimed in claim 13, wherein the threshold is determined by a resolution of the comparator.

18. The calibration method as claimed in claim 13, wherein a target voltage corresponding to the target code exceeds the sampling voltage by a predetermined voltage;
wherein the predetermined voltage is equal to a voltage corresponding to a least significant bit of the digital code.

19. The calibration method as claimed in claim 18, wherein a voltage corresponding to the initial code is less than the sampling voltage;
wherein the target voltage exceeds the voltage corresponding to the initial code.

20. The calibration method as claimed in claim 11, further comprising:
when the difference voltage does not exceed the threshold, executing the step of determining whether the difference voltage exceeds the threshold by the comparator.
